(19) United States
(12) Patent Application Publication
(10) Pub. No.: US 2014/0366930 A1
(43) Pub. Date: Dec. 18, 2014

(54) HYBRID SOLAR ENERGY RECOVERY SYSTEM

(71) Applicants: James DELSAUT, Sudbury (CA); Gilles LEDUC, Sudbury (CA)

(72) Inventors: James Desaut, Ontario (CA); Gilles Leduc, Ontario (CA)

(21) Appl. No.: 14/361,986

(22) PCT Filed: Dec. 6, 2012
(86) PCT No.: PCT/CA2012/001120

§ 371 Date: May 30, 2014

Related U.S. Application Data
(60) Provisional application No. 61/567,759, filed on Dec. 7, 2011.

(51) Int. Cl. H01L 31/0525; H01L 31/042; H01L 31/052

(52) U.S. Cl. CPC H01L 31/058; H01L 31/0524; H01L 31/0424
USPC 136/248

(57) ABSTRACT

A hybrid solar energy recovery system comprises a frame and a dual-purpose solar energy recovery plate mounted to the frame. The plate has a plurality of lenses on an upper surface of the plate for concentrating incident solar radiation on the plate, the plate comprising a heat exchanger to recover thermal energy and a plurality of photovoltaic cells for generating an electric current in response to solar radiation incident on the photovoltaic cells. A single system can thus provide both electric power, hydronic heating and domestic hot water.

### TECHNICAL FIELD

The present technology relates generally to solar energy and, in particular, to solar systems for hydronic heating and/or incorporating photovoltaic cells.

### BACKGROUND

With rising energy costs and increasing concerns over the climatic effects of greenhouse gases released from the combustion of hydrocarbons, there is now more than ever a powerful incentive to find clean energy solutions. One of the most promising green technologies is solar power. Many solar energy collection systems are known in the art. In general, they fall into two categories: photovoltaic (i.e. photo-electric) cells that directly generate an electric current and passive solar heating systems that absorb solar energy and conduct the heat to water or other heating fluid. Some such passive systems heat water in a sun-exposed conduit, e.g. a roof-top conduit, for various applications such as preheating water for a hot-water tank or warming water for a swimming pool.

It is also known in the art of solar power to include in such systems a means for concentrating and focusing the sun's radiation as well as mechanical means for tracking the sun so as to maintain the focusing mechanism in an orthogonal position relative to the direction of the sun's rays. These systems use reflecting and/or refracting focusing mirrors and lenses, such as parabolic reflectors and convex lens or Fresnel-type lenses, to focus and concentrate a relatively large surface area of incident solar radiation upon a small surface area to be heated. Focusing and/or concentrating technologies are disclosed, for example, in U.S. Pat. Nos. 4,257,401; 4,168,696; 4,148,300; 4,038,971 and 4,011,858, which are hereby incorporated by reference in their entireties. Mechanical devices for tracking the sun are disclosed, for example, in U.S. Pat. No. 4,153,039; 4,068,653; 3,999,389 and 4,275,710 which are also hereby incorporated by reference in their entireties.

Some other exemplary solar technologies are disclosed in U.S. Pat. Nos. 3,929,121; 4,307,710; 4,509,502; 4,823,772; 5,645,045; and 7,388,146 and also in US Patent Application Publication 2009/0114212, all of which are hereby incorporated by reference in their entireties.

As noted above, the most common techniques for harnessing the sun's energy involve either the use of photoelectric solar panels or the reflection/concentration of sun rays (via a mirror or other device) to a focal collecting point where that concentrated solar energy is then converted to various other forms of energy through conventional energy producing techniques. A common problem with these prior-art technologies for solar energy recovery is that they require large amounts of surface area (in the form of solar cells, mirrors, lenses, etc.) to produce the requisite energy.

It is estimated that approximately 11,000 Watts of energy are required to satisfy the power requirements of a typical household having a moderately sized home of 1000 to 1500 square feet. Based on the efficiency of most current solar panels, 10,000 square feet of solar panels would be required to generate the energy for a single household. This would occupy more space than the average household would be able or willing to devote to solar energy recovery, not to mention the issue of capital expenditure to set up the paneling or mirrors.

Because of the problems of solar panel size and set-up cost, solar energy is impractical for most people and does not yield a financial return on investment. A technology that addresses these problems would thus be highly desirable. Therefore, despite many advancements in the art, there remains a need in the industry for a hybrid solar energy recovery system that can, in a single compact unit, generate both electric power and provide hydronic heating.

### SUMMARY

In general, the present invention provides a novel system that incorporates both photovoltaic cells for generating electricity and passive solar thermal energy recovery for hydronic heating in a single compact device. The device can be mounted to a movable frame that tracks the movement of the sun to optimize energy recovery.

Thus, an inventive aspect of present disclosure is a hybrid solar energy recovery system comprising a frame and a dual-purpose solar energy recovery panel assembly mounted to the frame. The dual-purpose panel assembly has a plurality of lenses for concentrating incident solar radiation onto a heat exchanger to recover thermal energy and a plurality of photovoltaic cells for generating an electric current in response to solar radiation incident on the photovoltaic cells. The panel assembly in one embodiment includes a dual-purpose solar energy recovery plate housing the lenses and photovoltaic cells that is mounted above a heat exchanger plate housing the heat exchanger. The heat exchanger plate in turn is disposed above, or mounted to, the frame. In one embodiment, the frame is a movable frame that tracks the movement of the sun.

Other aspects of the present invention are described below in relation to the accompanying drawings.

### BRIEF DESCRIPTION OF THE DRAWINGS

Further features and advantages of the present technology will become apparent from the following detailed description, taken in combination with the appended drawings, in which:

FIG. 1 is an isometric view, from a left frontal perspective, of a novel hybrid solar energy recovery system in accordance with an embodiment of the present invention;

FIG. 2 is another isometric view, from a rear lateral perspective, of the hybrid solar energy recovery system depicted in FIG. 1;

FIG. 3 is a rear view of the hybrid solar energy recovery system depicted in FIG. 1; and

FIG. 4 is a top plan view of a lens plate that is incorporated into the hybrid solar energy recovery system of FIG. 1;

FIG. 5 is an isometric view of the underside of the lens plate of FIG. 4;

FIG. 6 is an isometric view of a solar panel and heat exchanger assembly in accordance with another embodiment of the present invention;

FIG. 7 is a front view of the assembly of FIG. 6;

FIG. 8 is a front view of a solar panel and heat exchanger assembly having a counterweight frame in accordance with another embodiment of the present invention; and

FIG. 9 is a rear isometric view of the assembly and counterweight frame of FIG. 8.

It will be noted that throughout the appended drawings, like features are identified by like reference numerals.

### DETAILED DESCRIPTION

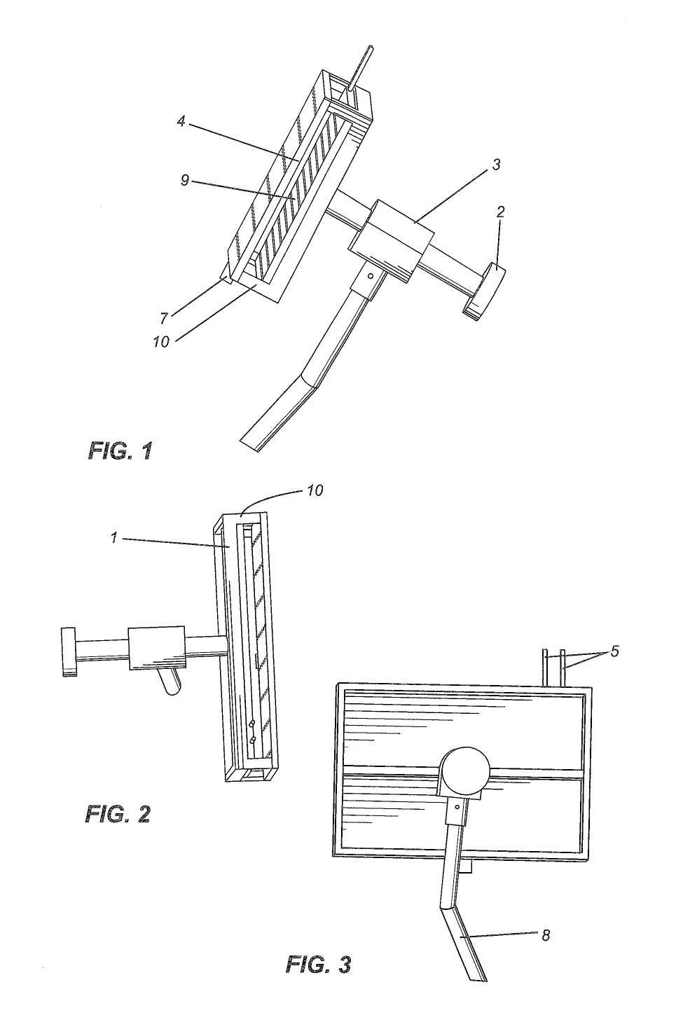

FIGS. 1-3 illustrate a novel hybrid solar energy recovery system in accordance with an embodiment of the present invention. The hybrid solar energy recovery system depicted by way of example in these figures comprises a frame denoted by reference numeral 1, a heat exchanger plate 9 disposed above the frame, and a dual-purpose solar energy recovery plate 4 mounted to the frame. The dual-purpose plate has a plurality of lenses 11 for concentrating incident solar radiation onto the heat exchanger plate to recover thermal energy and a plurality of photovoltaic cells 12 for generating an electric current in response to solar radiation incident on the photovoltaic cells. The plate is dual-purpose because it not only generates electric power using the photovoltaic cells but has lenses to concentrate the incident solar light on a heat exchanger plate disposed beneath the dual-purpose plate. The photovoltaic cells may utilize High-Concentration Photovoltaics (HCPV). The lenses may utilize micro-optic solar concentrator technology.

For the purposes of this specification, the dual-purpose plate (having the lenses and photovoltaic cells) together with the heat exchanger define a panel assembly, i.e. a dual-purpose solar energy recovery panel assembly that is mounted to the frame.

Accordingly, the hybrid solar energy recovery system may also be understood as comprising a frame and a dual-purpose solar energy recovery panel assembly mounted to the frame, wherein the dual-purpose panel assembly has a plurality of lenses for concentrating incident solar radiation onto a heat exchanger (which may be embedded within a plate) to recover thermal energy and a plurality of photovoltaic cells for generating an electric current in response to solar radiation incident on the photovoltaic cells.

In a main embodiment, the panel assembly comprises the dual-purpose solar energy recovery plate (having the lenses and photovoltaic cells) and a heat exchanger plate housing the heat exchanger. The underside of the dual-purpose plate (i.e. the top plate or cover plate) may, in one embodiment, have a heat-reflective finish or coating to reflect radiated heat back to the heat exchanger plate to maximize the heat exchanger's efficiency and to minimize unwanted heat transfer to the dual-purpose plate.

In one embodiment, the frame is a movable frame. The movable frame may move automatically by tracking the position of the sun. Optimal solar energy recovery is achieved by maintaining the frame and dual-purpose plate orthogonal to the incident solar radiation. The system may include a controller 6 for actuating a biaxial rotation mechanism 3 for moving the movable frame so as to track movement of the sun. The system may include a sun sensor 7 for sensing a position of the sun and for providing a signal to the controller. The controller maximizes the efficiency of energy recovery by ensuring that the dual-purpose plate remains as orthogonal as possible to the sun rays. In a tested embodiment, the controller maintains the plate orthogonal to the sun rays within a variance of +/−1%. The controller sends control signals to the biaxial rotation mechanism, which may utilize an electric motor and suitable gears to provide X & Y axis mobility. An optional counterweight 2 may be provided to balance the mechanism so as to minimize the power draw required to move the frame.

In one embodiment, the system further comprises a stand 8 mounted to the frame. The stand is adapted to be connected to an immovable structure, e.g. a house, apartment, or other dwelling or building, a shed, or other structure. Any suitable mechanical attachment means, fastening means, anchoring means or connecting means may be employed for anchoring or fastening the stand to the immovable structure. In another embodiment, the unit may be ground-mounted (i.e. the frame is supported on the ground with a frame, base, pedestal or other such support member). In a further embodiment, the unit may be mounted on a vehicle such as a recreational vehicle, camper, etc. (i.e. the frame may be mounted to any portion of the vehicle). In yet another embodiment, the system may be portable. The system may be easily retrofitted to any circulatory heating system by reconnecting the inlet and outlet lines to the system to be retrofitted. A portable system could be used in a variety of applications, for instance at a camp, cottage, or other outpost, or with a recreational vehicle.

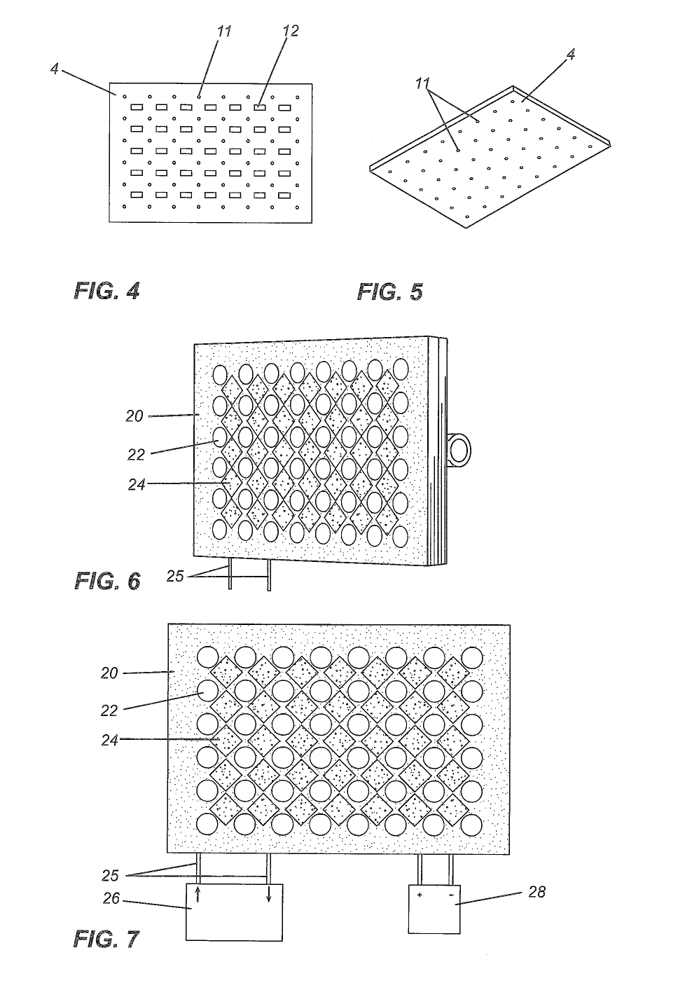

In one embodiment, the plurality of lenses and the plurality of cells are arranged in alternating rows and columns. One specific example implementation is depicted in FIGS. 4 and 5. In this specific example, which is intended solely to illustrate one particular implementation, there are 48 lenses and 35 photovoltaic cells. The lenses in this specific example are arranged in an array of 8×6 lenses and the cells are arranged in an array of 7×5 cells. The rows and columns of lenses and cells are interspersed, i.e. there is one row or column of lenses, followed by a row or column of cells, followed by a row or column of lenses, etc. It bears emphasizing that the implementation depicted in FIGS. 4 and 5 is merely an example. It will be appreciated that the number of lenses may be varied. Likewise, the number of cells may be varied. Furthermore, it should be understood that the configuration or layout of lenses and cells as alternating rows and columns is merely exemplary. Other configurations or layouts may be employed. Finally, the even spacing between the rows and columns of lenses and cells is also exemplary. An irregular spacing may also be used.

In an embodiment, the lenses are embedded in a honeycombed holder such that each and every crystal/lens will have the identical focal properties when the sun's rays pass through each lens. The distance from the top surface of the lens to this focal point on the heat-exchanger plate may be short in length (e.g. 3 to 6 inches) although the size, orientation and shape of the lenses may be varied for different applications.

In one embodiment, the heat exchanger plate is mounted to an upper surface of the frame. The frame may comprise a plurality of support arms 10 or struts for supporting the dual-purpose plate. The dual-purpose plate may be mounted to the support arms of the frame in a substantially parallel and spaced-apart relation to the heat exchanger plate, thereby defining an air gap between the heat exchanger plate and the dual-purpose plate. In one specific embodiment, the air gap is a function of the focal length of the lenses. Specifically, the air gap may be equal to the focal length of the lenses to optimize the concentration of light energy on specific target locations on the heat exchanger plate.

In one embodiment, the heat exchanger comprises one or more hydronic heating conduits embedded in a heat-conductive alloy, the conduits being substantially aligned with the lenses. An inlet and outlet 5 are provided for the heat exchanger. The alloy would have a melting point significantly higher than the maximum localized temperature that could be produced by the lenses. Once the alloy is heated by solar radiation, a liquid (e.g. water, propylene glycol, etc.) in the conduits is heated. This liquid transfers heat to various heating elements or thermal conductive units to provide thermal energy to a residential house or the environment of a huge building complex. The excess thermal energy in the circulating liquid may be stored within a well insulated thermal storage container.

In one embodiment, the system further comprises temperature sensors to monitor a temperature of a fluid in the hydronic heating conduits and to provide a temperature signal to a controller to selectively enable and disable the system. For example, the controller may cause the frame to move away from the sun, to reduce the solar load until the temperature drops to below the maximal operating threshold.

In another embodiment, instead of one integrated multi-function controller, three separate controllers may be provided. A first controller controls X and Y positioning of the device by sensing/tracking the movement of the sun. A second controller may receive signals from temperature sensors to monitor the temperature of the heat exchanger plate, to monitor the temperature of the conduit liquid at the inlet and to monitor the temperature of the conduit liquid at the return. The second controller may control a pump (e.g. a 12V DC or 120V AC pump) to control the liquid delivered to the heat exchanger and supply tanks. A third controller will derive energy from the photovoltaic system to supply direct current (e.g. 12V DC) to energize the battery (or batteries), capacitor(s) or other storage device(s), for example, via a trickle charge system. This battery/capacitor/storage system will supply direct current (e.g. 12 V DC) to power all controllers (i.e. the first, second and third controllers). Optionally, the third controller can supply direct current (e.g. 12 V DC) to an inverter to convert stored energy to alternating current (e.g. 120V AC) for domestic use (e.g. lighting) and/or for emergency back-up power.

The embodiments of the present invention at least partially address some of the identified shortcomings of the prior art. The hybrid solar energy recovery system captures the energy of the sun's rays for residential or commercial applications.

The system (or “device” or “unit”) disclosed herein and illustrated by way of example in FIGS. 1-5 is a compact solar energy recovery system that harnesses the sun's energy by concurrently generating electrical power using photovoltaic cells while also focusing the sun's rays through one or more lenses (also referred to as “crystals”) onto a passive thermal recovery plate (heat exchanger). The system, and in particular the heat exchanger plate, may be manufactured from any one of various materials (e.g. stainless steel or any other metals or alloys, etc.). The design is scalable so the system can be constructed in varying sizes or shapes. As noted above, the lenses and cells can be arranged in any number of different configurations or layouts.

The series of lenses provides a series of thermal focal points where focused energy is absorbed, collected and conducted through a receiving metal, alloy or other substance. The heat may be transferred by conduction, convection, radiation or any combination thereof. Heat may be converted into other forms of energy using known techniques. For example, the thermal energy can convert water into steam to drive a mini-turbine or other mini-generator. In another embodiment, the system on a larger scale could be utilized as an efficient and powerful source of steam production which, in turn, could move turbines to produce electricity for mass consumer consumption. Alternatively, as another example, the photovoltaic cell(s) can generate DC voltage to separate H₂O (into hydrogen and oxygen) and the resulting hydrogen can be used to generate electricity using a hydrogen fuel cell.

This recovered solar energy can be utilized for commercial or residential consumption in various ways. In one embodiment, a fluid is circulated through the heated alloy or other metal to thereby transfer heat to the circulating fluid circulating in the heat exchanger. The fluid then transfers its heat to existing heating elements or circulating systems in a retro fit to enable the consumer to utilize this heat for their particular purpose (e.g. home heating, commercial heat applications, domestic or commercial hot water tank heating, hydronic radiant floor heating, driveway heating, swimming pool heating, etc.). In addition to lens-amplified passive thermal heating, the embodiments of the invention also incorporate photoelectric energy production which can simultaneously generate electrical energy for back-up storage and to provide power for the controller and motor while thermal energy is being collected.

Embodiments of the present invention use a relatively small square footage for the amount of energy it will produce. Although the primary utility of this novel system is to collect solar power where space is highly limited, it should be appreciated that the system is scalable and larger scale versions of the system may be used to increase its capacity to produce more energy.

The system disclosed herein thus provides a cost-effective and compact (space-saving) eco-friendly utility device that will not only save consumers money but also save the environment from current fossil fuel consumption. The unit also contributes to a much greener landscape (i.e. there would be no need for a plethora of mirrors or panels). Depending on the weather of the locality where the system is utilized, an average user can expect between 30% to 50% supplemental cost savings on their thermal energy bill (just from home/business heating and hot water utilization). If the locality chosen has many more solar hours available, one could expect even greater cost savings.

In the disclosed embodiments, the invention remedies both the financial and space limitations by enabling the average residential consumer or commercial business to provide thermal energy to heat residences and businesses and provide a continuous hot water supply in colder climates and, inversely, through another embodiment involving thermal energy conversion to electricity, cool down their accommodations or places of commerce in the summer. This invention can be used to retrofit a house or building. The system can be mounted at any location where the sun's rays can be tracked to ensure optimum efficiency.

Embodiments of the invention may incorporate various safety features such as an auto shut off switch triggered by sensing an overheating condition (as described above). Thermal sensors may be placed, as noted above, at the inlet and outlets of the heat exchanger to monitor temperatures of incoming and outgoing fluid. Temperature sensors may also be placed within a fluid storage container or at any other location in the present system or any connected systems. Auto shut off may also be triggered by a malfunction condition (e.g. an electrical failure or by an error message from the controller). Shut off may be achieved by turning the unit completely away from the sun.

The unit may be weather proofed by encasing the unit in a suitable protective casing. A protective film over the lenses may be provided to protect the lenses from weather and also to help minimize heat degradation.

The unit may provide a space (e.g. on the back of the unit) with instructions for installation, safe operation and maintenance.

FIG. 6 and FIG. 7 depict a dual-purpose solar energy recover panel assembly (“panel assembly”) in accordance with another embodiment of the present invention. The panel assembly 20 comprises both a plurality of lenses 22 and a plurality of photovoltaic cells 24. In the embodiment illustrated in FIG. 6, the panel assembly 20 is substantially rectangular although other shapes may be employed. The photovoltaic cells 24 in this illustrated embodiment are substantially square and are non-orthogonal relative to the sides of the panel. In the specific embodiment illustrated, the cells 24 are rotated approximately 45 degrees relative to the sides of the panel assembly 20. This arrangement permits a large number of lenses 22 and photovoltaic cells 24 to be densely placed on the panel. In the specific configuration shown by way of example in FIG. 6 and FIG. 7, there are 48 lenses (8×6) and 35 photovoltaic cells (7×5) arranged in alternating rows and columns of lenses and cells. As will be appreciated, the number of lenses and the number of cells as well as their geometry, relative size, spacing and configuration, may be varied in other embodiments. The panel assembly 20 includes inlet and outlet tubes (or pipes) 25 for connecting to a hot water system 26 shown in FIG. 7. The photovoltaic cells are connected to an energy storage unit 28 as shown in FIG. 7. The photovoltaic cells may utilize High-Concentration Photovoltaics (HCPV). The lenses may utilize micro-optic solar concentrator technology.

In one embodiment, the photovoltaic cells are embedded in the dual-purpose plate (top plate) such that the top surface of the dual-purpose plate (top plate) of the panel assembly is substantially flat which when oriented orthogonally to the sun maximizes solar radiance absorption. In one embodiment, there is an intermediate plate disposed between the top plate and the heat exchanger plate, the intermediate plate having holes aligned with the lenses. Thus, in one embodiment, the panel assembly comprises the top plate and an optional intermediate plate which is in turn mounted in a spaced-apart relationship to the heat exchanger plate to create an air gap between the intermediate plate and the heat exchanger plate. In other embodiments, there may not be an air gap.

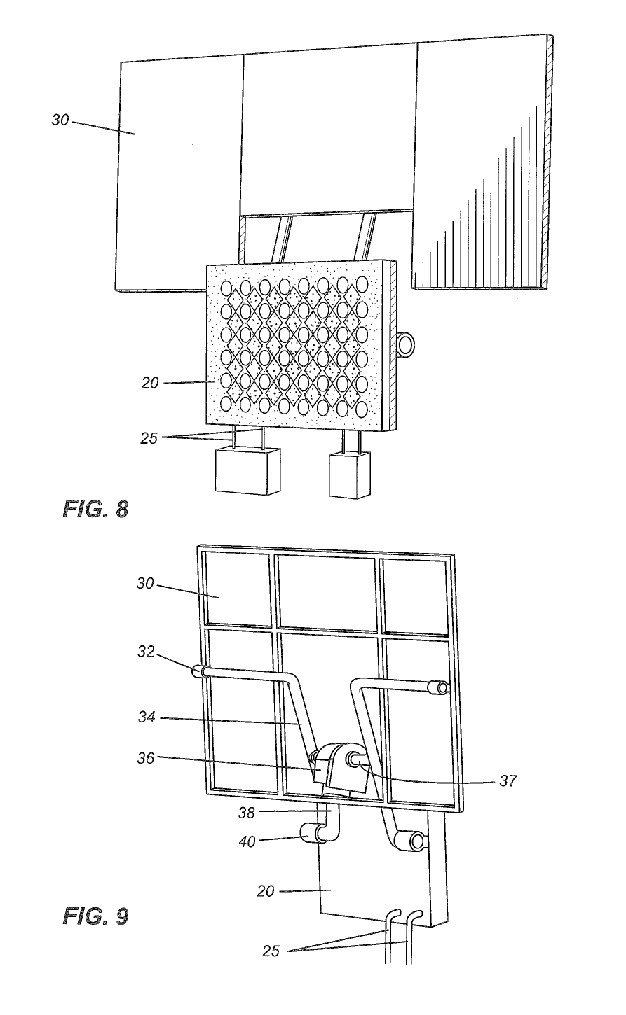

FIG. 8 and FIG. 9 depict a front view of a solar panel and heat exchanger assembly having a counterweight frame 30 in accordance with another embodiment of the present invention. This counterweight frame takes the places of the optional counterweight 2 described above. The counterweight frame 30 improves the dynamics of the mechanism and minimizes the energy requirements to rotate the panel assembly to track the sun. FIG. 9 shows one exemplary mechanism for mounting the panel assembly 20 to the counterweight frame 30. As shown in this figure, a pair of upper rotational supports 32 are mounted to the rear face of the counterweight frame 30. Each of the upper rotational supports 32 defines a bore for receiving and rotationally supporting a respective one of a pair of upper support arms 34. The upper rotational supports 32 may include journals, bushings or bearings. The upper support arms 34 connect to a drive shaft 37 that extends from an electric motor 36. The electric motor 36 is analogous to the biaxial rotator mechanism 3 described above with reference to FIG. 1. The electric motor 36 and biaxial rotator mechanism 3 act as a rotator to rotate the panel assembly. As will be appreciated, any suitable motor, rotator or biaxial rotation mechanism may be used to move the panel assembly. In other variants, the panel assembly may be rotated using a rotational mechanism having one or more linear actuators and a means for converting linear motion of the linear actuator(s) into rotational motion of the panel assembly. As further depicted in FIG. 9, the electric motor 36 is also connected via the drive shaft 37 to a pair of lower support arms 38 which rotate within a pair of lower rotational supports 40 mounted to the back of the panel. The lower rotational supports 40 may include journals, bushings or bearings. In some embodiments, the upper and lower support arms are integrally formed as a single rod or member.

As shown in FIG. 9, the upper and lower support arms 34, 38 each comprises an upper member and a lower member that are both orthogonal to the drive shaft extending from the motor. Each of the upper and lower support arms 34, 38 also comprises parallel members that are parallel to the drive shaft 37 of the motor 36 for engaging the rotational supports 32, 40. The rotational supports 32, 40 are thus parallel to the drive shaft 37 of the motor 36. As shown in FIG. 9, the upper and lower members curve or bend 90 degrees into the parallel member. In operation, the motor 36 exerts torque on the arms 34, 38, thereby causing rotation of the panel assembly 20 and a balancing rotation of the counterweight frame 30. In one embodiment, the counterweight frame comprises a plurality of photovoltaic cells for additional electricity-generating capacity.

The panel assembly may be opened or closed. In the latter case, a closed panel assembly may include a hermetically sealed space that can contain a vacuum, partial vacuum, a gas other than air, e.g. an inert gas, or pressurized air or a pressurized gas. The captive gas may be used to vary the heat transfer properties and/or the light transmission properties between the lens and the heat exchanger.

In one embodiment, the system may include wings with additional photovoltaic cells on one or more sides of the panel assembly. The wings may be permanently attached or detachably mounted. The wings may be foldable or collapsible or these may slide out, or be deployed in any other way. In one embodiment, the wings may be deployed to capture maximum solar load and retracted at night or when solar intensity falls below a prescribed threshold.

Calibration of the system may be done manually, for example by adjusting screws or threaded members on each corner of the unit which, when turned, move the lens plate slightly up or down to thus optimize the focus of the lens focal points and thus to improve the heating efficiency of the unit. Thus, the rotator provides an X-axis and Y-axis axis motion while the calibration mechanism provides Z-axis (movement up and down) such that there is motion in three degrees of freedom.

In a further embodiment, automatic self-calibration for automated precise calibration of the lens plate focal points may be based on feedback signals from thermal sensors embedded or installed in the unit itself. In the automatic self-calibration option, tiny motors replace the manual threaded screws to achieve the up and down movement. The direction and degree of adjustment is determined by the feedback of the internal thermal sensors and the parameters set for optimal efficiency within the unit. A microcontroller or microprocessor may be provided to self-calibrate the unit in response to feedback signals received from sensors in the panel assembly.

This new technology has been described in terms of specific implementations and configurations which are intended to be exemplary only. Persons of ordinary skill in the art will appreciate that many obvious variations, refinements and modifications may be made without departing from the inventive concepts presented in this application. The scope of the exclusive right sought by the Applicant(s) is therefore intended to be limited solely by the appended claims.

1. A hybrid solar energy recovery system comprising:
a frame;
a dual-purpose solar energy recovery panel assembly mounted to the frame, the dual-purpose panel assembly having:
a plurality of lenses for concentrating incident solar radiation onto a heat exchanger to recover thermal energy; and
a plurality of photovoltaic cells for generating an electric current in response to solar radiation incident on the photovoltaic cells.

2. The system as claimed in claim 1 wherein the panel assembly comprises:
a dual-purpose solar energy recovery plate comprising:
the plurality of lenses for concentrating the incident solar radiation onto a heat exchanger plate housing the heat exchanger, the heat exchanger plate being mounted beneath the dual-purpose plate; and
the plurality of photovoltaic cells for generating the electric current in response to the solar radiation incident on the photovoltaic cells.

3. The system as claimed in claim 1 wherein the frame is a movable frame.

4. The system as claimed in claim 3 comprising a controller for actuating a biaxial rotation mechanism for moving the movable frame so as to track movement of the sun.

5. The system as claimed in claim 4 comprising a sun sensor for sensing a position of the sun and for providing a signal to the controller.

6. The system as claimed in claim 1 further comprising a stand mounted to the frame, the stand being adapted to be connected to an immovable structure.

7. The system as claimed in claim 1 wherein the plurality of lenses and the plurality of cells are arranged in alternating rows and columns.

8. The system as claimed in claim 1 wherein the heat exchanger plate is mounted to an upper surface of the frame.

9. The system as claimed in claim 8 wherein the frame comprises a plurality of support arms for supporting the dual-purpose plate.

10. The system as claimed in claim 9 wherein the dual-purpose plate is mounted to the support arms of the frame in a substantially parallel and spaced-apart relation to the heat exchanger plate, thereby defining an air gap between the heat exchanger plate and the dual-purpose plate.

11. The system as claimed in claim 10 wherein the air gap is a function of the focal length of the lenses.

12. The system as claimed in claim 1 wherein the heat exchanger plate comprises hydronic heating conduits embedded in a heat-conductive alloy, the conduits being substantially aligned with the lenses.

13. The system as claimed in claim 1 further comprising temperature sensors to monitor a temperature of a fluid in the hydronic heating conduits and to provide a temperature signal to a controller to selectively enable and disable the system.

14. The system as claimed in claim 1 further comprising a counterweight frame.

15. The system as claimed in claim 1 comprising a calibration mechanism for adjusting a distance between the lenses and the heat exchanger.

16. The system as claimed in claim 15 further comprising a microcontroller for automatically controlling the calibration mechanism based on a feedback signals from sensors in the panel assembly.

17. The system as claimed in claim 14 wherein the counterweight frame comprises a plurality of photovoltaic cells.
